(19) United States
(12) Patent Application Publication
(10) Pub. No.: US 2009/0293804 A1
(43) Pub. Date: Dec. 3, 2009

(54) Method of shoulder formation in growing silicon single crystals

(76) Inventors: Hiroaki Taguchi, Tokyo (JP); Hideki Hara, Tokyo (JP); Ryoichi Kaito, Tokyo (JP)

Correspondence Address: CLARK & BRODY, 1090 VERMONT AVENUE, NW, SUITE 250, WASHINGTON, DC, 20005, US

(21) Appl. No.: 12/457,067

(22) Filed: Jun. 1, 2009

(30) Foreign Application Priority Data
Jun. 3, 2008 (JP) 2008-145236

(51) Int. Cl. C30B 15/22

(52) U.S. Cl. 117/35; 117/13

(57) ABSTRACT

A method of shoulder formation in growing silicon single crystals by the CZ method which comprises causing the taper angle to vary in at least two stages, desirably three stages or four stages, can inhibit the occurrence of dislocations in the shoulder formation step and thereby improve the yield and increase the productivity. As the number of stages resulting from varying the taper angle is increased, possible disturbances to occur at crystal growth interfaces and incur dislocations can be reduced and, further, when the above shoulder formation method is applied under application of a transverse magnetic field having a predetermined intensity, the occurrence of dislocations can be inhibited and defect-free silicon single crystals suited for the manufacture of wafers can be grown with high production efficiency. Therefore, the method is best suited for the production of large-diameter silicon single crystals with a diameter of 450 mm which are to be applied to manufacturing semiconductor devices.

### BACKGROUND OF THE INVENTION

1. Field of the Invention

The present invention relates to a method of forming the shoulder portion in growing silicon single crystals using the Czochralski method (hereinafter referred to as “CZ method”) and, more particularly, to a method of forming the shoulder portion in growing silicon single crystals, in which occurrence of dislocations is inhibited in the step of shoulder formation by defining the shape of the shoulder portion.

2. Description of the Related Art

A method of growing silicon single crystals by the CZ method comprises placing silicon raw materials for semiconductor manufacture in a crucible, heating and melting the silicon materials, immersing a seed crystal into the melt and pulling up the seed crystal while rotating the same to thereby causing a silicon single crystal to grow from the bottom of the seed crystal; this method is widely employed for the production of silicon single crystals used for semiconductor substrates.

FIG. 1 is a schematic representation, in vertical cross section, of an essential configuration of a single crystal pulling apparatus suited for growing silicon single crystals by the CZ method. As shown in FIG. 1, this pulling apparatus comprises a heater 1, disposed around a crucible 2 in an approximately concentric manner, for heating the semiconductor silicon raw materials fed into the crucible 2 and maintaining the materials in a molten state, and a thermal insulator 3 that is disposed in the vicinity of the outside of the heater.

The crucible 2 has a double structure and is constituted of an inner layer holding vessel 2a made of quartz in the form of a bottomed cylinder (hereinafter referred to as “quartz crucible”) and an outer layer holding vessel 2b which is made of graphite in the form of a bottomed cylinder and is fitted to the outside of the quartz crucible 2a for holding the same (hereinafter referred to as “graphite crucible”), and the crucible 2 is fixed to the upper end of a supporting shaft 4 which is rotatable, and movable up and down.

A pull wire 6 rotating at a predetermined speed either in the reverse direction or the same direction on the same axis relative to the supporting shaft 4 is disposed above and on the same axis as the crucible 2 tah contains the melt 5, and a seed crystal 7 is held at the lower end of the pull wire.

On the occasion of pulling up a silicon single crystal using the pulling apparatus thus configured, a predetermined amount of semiconductor silicon raw materials (generally a bulky or granular polycrystalline silicon raw materials) are fed into the crucible 2 and heated and melted by means of the heater 1 disposed around the crucible 2 in an inert gas atmosphere (generally argon (Ar)) at a reduced pressure, and the seed crystal 7 held at the lower end of the pull wire 6 is then immersed into the surface layer of the melt 5 thus formed. Then, while the crucible 2 and pull wire 6 are rotated, the wire 6 is pulled up for growing a single crystal 8 at the lower end face of the seed crystal 7.

On the occasion of pulling up, the diameter of the single crystal 8 formed on the lower end face of the seed crystal 7 is reduced by adjusting the pulling speed and the melt temperature (temperature of the molten silicon) for the formation of a neck portion (narrowed portion) 9 and, after this necking step, the crystal is caused to gradually increase in diameter to form a cone 10 and further a shoulder portion 11.

Then, a main body portion (cylindrical portion) 12 to be used as a source material of product wafers is pulled up. After the length of the main body portion 12 reaches a predetermined level, the crystal diameter is caused to gradually decrease to form a tail (not shown), and the bottom tip of the tail is separated from the melt 5; a silicon single crystal 8 having a predetermined shape is thus obtained.

The above-mentioned necking is an essential step for. eliminating high-density dislocations introduced into the seed crystal due to heat shock upon contact of the seed crystal with the silicon melt. Through this step, those dislocations are eliminated.

However, in the step of cone and shoulder formation (hereinafter referred to as broadly “shoulder formation step”, encompassing cone formation) following the necking step, dislocations may occur in the crystal in certain instances.

When the diameter of the single crystal once reduced in the necking step is increased in the shoulder formation step, it is a general practice to lower the melt temperature and at the same time reduce the pulling speed. If the melt temperature is lowered abruptly, disturbances tend to be generated at the crystal growth interface, facilitating the occurrence of dislocations.

When the changes in melt temperature are slight, such disturbances are slight and dislocations hardly occur; however, the crystal growth becomes slow, and the shoulder portion becomes gentle (the gradient of the shoulder spreading becomes slight) in association with the pulling speed and a prolonged period of time is required for the main body diameter to reach a predetermined level, so that the length of the main body portion relative to the total length of the pulled-up single crystal becomes short. As a result, the productivity of silicon single crystals is reduced.

In view of the above problems, it has been a general practice to carry out shoulder formation while endeavoring to prevent dislocations from occurring based on the experiences accumulated in actual operations and taking the productivity into consideration. On that occasion, the angle of the shoulder portion relative to the lengthwise pull-up direction (gradient of the shoulder spreading) is generally made to be constant. However, dislocations may likely occur during shoulder formation, hindering advancing to the step of growing the main body portion without any trouble; this is one of the reasons why the yield of single crystals pulled up (hereinafter referred to as “yield” for short) is lowered and the productivity is reduced in silicon single crystal production.

On the other hand, large-diameter wafers are currently required to follow recent trends toward intensified integration in semiconductor devices, reduction in cost and improvement in productivity; accordingly, it is required to produce large-diameter silicon single crystals as source materials therefor. However, in the case of the production of large-diameter silicon single crystals having a diameter of 450 mm, for instance, the accumulation of results from actual operations is not yet abundant and it is currently premature to reliably inhibit dislocations from occurring in the step of shoulder formation while securing a high level of productivity.

### SUMMARY OF THE INVENTION

The present invention has been made in view of such a situation as mentioned above, and an object thereof is to provide a method of shoulder formation in growing silicon single crystals, in particular silicon single crystals having a large diameter of 450 mm, by the CZ method according to which method the occurrence of dislocations in the shoulder formation step can be inhibited, improvements in yield and productivity can be achieved accordingly.

In the course of investigations made by the present inventors to accomplish the above object, the inventors arrived at an idea that changes in angle, relative to the lengthwise direction of pulling up silicon single crystals, of the shoulder portion on the occasion of shoulder formation might result in inhibition of dislocations from occurring.

Conventionally, the shoulder formation is carried out based on the experiences in actual operations while attaching importance to the improvement in yield and in productivity, as mentioned hereinabove. There has never been any idea of varying the angle of shoulder portion relative to a lengthwise pull-up direction and, therefore, the angle of shoulder portion has been kept constant. If, however, dislocations are caused to occur by disturbances at the crystal growth interface, it becomes possible to extend the shoulder portion in a radial direction of single crystal, while inhibiting dislocations from occurring, by operating in a manner such that the shoulder portion varies in angle, for example, the shoulder portion angle is first maintained small (or, in other words, the spreading of the shoulder is made gentle to narrowly restrict radial spreading) to inhibit such disturbances and then the shoulder portion is extended by increasing in angle of shoulder in a stepwise manner so that the occurrence of disturbances in each step may be suppressed to the minimum.

If such a method of shoulder formation has been established, the method may be suitably utilized even in cases where the accumulation of results in actual operations is not yet abundant, for example in producing large-diameter silicon single crystals having a diameter of 450 mm.

The present invention has been made based on such idea and results of investigations, and the gist thereof consists in the following method of shoulder formation in growing silicon single crystals.

The present invention provides a method of shoulder formation, characterized in that the taper angle in transition from a neck portion to a main body portion is caused to vary in at least two steps in growing silicon single crystals by the CZ method.

The term “taper angle” as used herein means the above-mentioned angle of shoulder portion relative to a lengthwise pull-up direction and, as shown in FIGS. 2-4 to be referred to later herein, refers to each angle (λ₁, λ₂, α₁, α₂, . . . , etc.) formed by extended lines, left and right, representing the shoulder portion (bold solid lines in each of FIGS. 2-4) in the vertical cross section showing the central axis C, of the silicon single crystal respectively along the slanting shoulder portion.

The phrase “in transition from a neck portion to a main body portion” refers to the shoulder portion progressively formed from the neck portion toward the main body portion (the cone formation being included herein) and, more specifically, refers to the portion from the periphery (namely, diameter) of the neck portion to the periphery (diameter) of the main body portion. In the case of producing large-diameter silicon single crystals having a diameter of 450 mm and when the neck portion diameter is 10 mm, the portion in concern correspond to a transition area from a radius of 10/2 mm to a radius of 450/2 mm of each single crystal.

According to the above-defined shoulder formation method of the present invention, when the taper angle is caused to vary in three stages, namely taper angles of α₁, α₂ and α₃, and further when the condition α₁<α₂<α₃ is satisfied, disturbance-causing factors can be further reduced as compared, for example, with the case of varying the taper angle in two stages. This is a desirable embodiment of the present invention (hereinafter referred to as “first embodiment”).

Furthermore, when the taper angle is caused to vary in four stages, β₁, β₂, β₃ and β₄, respectively and, further, when the conditions β₁<β₂<β₃ and β₃>β₄ are satisfied, it becomes possible to reduce disturbance-causing factors to thereby inhibit dislocations from occurring and, at the same time, it becomes possible to allow the transition from the shoulder formation step to the main body portion formation step without troubles. Such is a more desirable embodiment of the present invention (hereinafter referred to as “second embodiment”).

The shoulder formation method of the present invention, including the above-mentioned embodiments, can be properly utilized also in growing large-diameter silicon single crystals having a diameter of 450 mm. The term “diameter of 450 mm” as used herein means that silicon single crystals to be supplied as source materials for manufacturing wafers as product have a diameter of 450 mm; thus, single crystals as pulled up may also have a diameter of 460-470 mm in certain cases.

Further, the shoulder formation method of the present invention (including the above-mentioned embodiments) may also be carried out in a manner such that silicon single crystals are grown under application of a transverse magnetic field with an intensity of not less than 0.1 T. In this case, the effect of application of the transverse magnetic field can also be obtained in addition to the effects of the present invention; this embodiment is thus a particularly desirable one.

By employing the shoulder formation method of the present invention in growing silicon single crystals, it becomes possible, in growing silicon single crystals by the CZ method, to inhibit dislocations from occurring in the shoulder formation step and thereby achieve improvements in yield and, accordingly, in productivity. The number of changes in taper angle is desirably as many as possible since an increased number of stages of taper angle changes can result in further reducing dislocation-caused disturbance factors.

The shoulder formation method of the present invention can be suitably utilized also in growing large-diameter silicon single crystals having a diameter of 450 mm. Further, when silicon single crystals are grown under application of a transverse magnetic field with a predetermined intensity, the dislocation-inhibiting effect in the shoulder formation step and the point defect introduction-inhibiting effect are simultaneously produced, whereby a yield improvement is achieved and the rate of crystal growth is increased, with the desirable effect that high levels of production efficiency can be attained.

### BRIEF DESCRIPTION OF THE DRAWINGS

FIG. 1 is a schematic representation, in vertical cross section, of an essential configuration of a single crystal pulling apparatus suited for growing silicon single crystals by the CZ method.

FIG. 2 is a figure for illustrating the shoulder formation method of the present invention, and is a schematic representation of a silicon single crystal at a certain time point in the course of pulling up the same as shown in vertical cross section showing the central axis of the silicon single crystal.

FIG. 3 is a figure for illustrating the shoulder formation method of the present invention, and is a schematic representation of another silicon single crystal at a certain time point in the course of pulling up the same as shown in vertical cross section showing the central axis of the silicon single crystal.

FIG. 4 is a figure for illustrating the shoulder formation method of the present invention, and is a schematic representation of yet another silicon single crystal at a certain time point in the course of pulling up the same as shown in vertical cross section showing the central axis of the silicon single crystal.

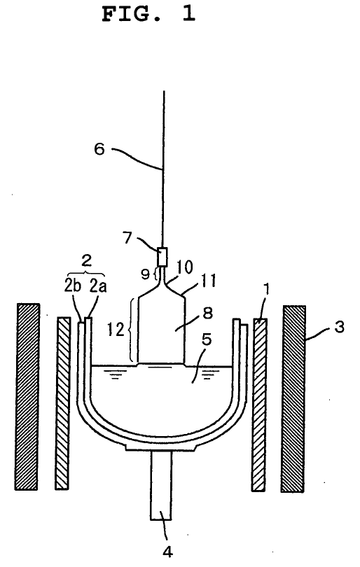

### DETAILED DESCRIPTION OF THE PREFERRED EMBODIMENTS

The shoulder formation method in growing silicon single crystals according to the present invention comprises causing the taper angle from the neck portion to the main body portion to vary in at least two stages in growing silicon single crystals by the CZ method.

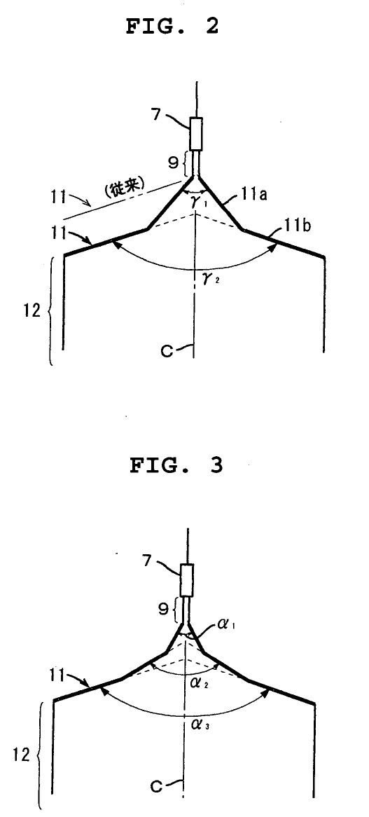

FIG. 2 is a figure for illustrating the shoulder formation method of the present invention and is a schematic representation of a silicon single crystal at a certain time point in the course of pulling up the same as shown in vertical cross section showing the central axis of the silicon single crystal. In this case, the taper angle is caused to vary in two stages. As shown in FIG. 2, a shoulder portion 11 (portion indicated by bold solid lines in the figure), which extends from the neck portion 9 to the main body portion 12, is formed subsequent to the formation, on the lower end face of the seed crystal 7, of the neck portion 9 reduced in diameter.

On that occasion, the taper angle is caused to vary in two stages λ₁ and λ₂. By this, a step 11a corresponding to the first stage and a step 11b corresponding to the second stage are formed. In the vertical cross section showing the central axis C of the silicon single crystal, the taper angle λ₁ is the one which is formed by extended lines of the segment indicating the first stage step 11a, from both the left and right sides toward the central axis C, and the angle λ₂ is the one which is formed by extended lines of the segment indicating the second stage step 11b toward the central axis C in the same manner.

The taper angle is caused to vary during the course of transition from the neck portion to the main body portion in at least two stages according to the shoulder formation method of the present invention, so that disturbances at the crystal growth interface may be reduced to the minimum to inhibit dislocations from occurring.

Conventionally, the shoulder portion 11 is formed without causing the taper angle to vary, for example as shown by the long dashed double-dotted lines in FIG. 2, and hence rapid decreases in melt temperature and pulling speed on the occasion of transfer to the formation of the shoulder portion 11 following the necking step cannot be avoided; as a result, an increased number of disturbances are provoked at the crystal growth interface, facilitating dislocations to occur. When, on the contrary, the taper angle is caused to vary in at least two stages, for example in the case where the number of stages in variation is 2, the first stage taper angle λ₁ can be made smaller, as indicated by bold solid lines in FIG. 2, than the conventional taper angle (equal to λ₂ in this example) (in other words, the gradient/slant can be rendered gentle relative to the central axis C), so that the occurrence of disturbances at the crystal growth interface can be reduced as compared with the conventional technique and, as a result, dislocations can be inhibited from occurring. The possible reduction in productivity is minimized by making the second stage taper angle λ₂ larger than λ₁ for completing the shoulder portion.

When the number of stages resulting from varying the taper angle is 2, as shown in FIG. 2, the angle λ₁ is desirably selected within the range of 1° to 120°, and the angle λ₂ in the range of 10° to 160°. When λ₁ is greater than the upper limit to the above range, the resulting condition will readily allow dislocations to occur and, when it is below the lower limit thereto, the diametral growth (extension) of the shoulder portion gets slow and lengthens the same, resulting in a reduced main body portion length. On the other hand, when λ₂ is in excess of the upper limit to the range mentioned above, dislocations tend to occur in the same manner as mentioned above and, when it is below the lower limit thereto, the widening of the shoulder portion gets slow and lengthens the same, so that the main body portion will become short and the productivity will be reduced.

The number of such stages resulting from varying the taper angle is not limited to 2 but may be 3 or more. On that occasion, the taper angle may be changed at any point from neck portion to main body portion. It is desirable that the number of such stages be increased since it becomes possible to further reduce disturbances at the crystal growth interface and thereby effectively inhibit dislocations from occurring in each stage as a result of gradual variation in taper angle from stage to stage.

The upper limit to the number of stages resulting from varying the taper angle is not particularly specified herein; it is desirable, however, to restrict the number to around five (5) since, when the number of such stages is excessively large, the procedure in the shoulder formation step (e.g. controlling of the single crystal pulling speed and melt temperature) becomes complicated and, further, the stability of the crystal growth interface is readily threatened in each stage of changing as a result of the frequent taper angle variations.

The relation between the varied taper angles according to the shoulder formation method of the present invention is not particularly specified herein. Generally, however, it is desirable that the taper angle be increased as the shoulder formation progresses from the neck portion to the main body portion side. This is because the ratio of the main body portion length to the whole length of the single crystal can be increased by sophisticatedly extending the shoulder portion and the productivity can be increased, as already mentioned hereinabove. In the above-mentioned case where the number of stages resulting from varying the taper angle is 2, the relation between the taper angles λ₁ and λ₂ is λ₁<λ₂, namely the desirable relation mentioned above.

In the following, the case where the number of stages resulting from varying the taper angle is three (3) or four (4) is described, referring to the figures.

FIG. 3 is a figure for illustrating the shoulder formation method of the present invention, and is a schematic representation of another silicon single crystal at a certain time point in the course of pulling up the same as shown in vertical cross section showing the central axis of the silicon single crystal. This is the case where the taper angle is varied to show three stages, corresponding to the first embodiment as mentioned above. The taper angle is varied to show three stages, namely α₁, α₂ and α₃, in that order on the occasion of forming the shoulder portion 11 (indicated by bold solid lines in the figure) extending from the neck portion 9 to the main body portion 12 subsequent to the formation, at the lower end face of the seed crystal 7, of the neck portion 9 reduced in diameter, as shown in FIG. 3.

In this case, the respective taper angles are selected to satisfy the condition α₁<α₂<α₃, so that it may become possible to effectively inhibit dislocations from occurring and, at the same time, to increase the productivity by extending the shoulder portion in an accelerated manner in the diametric direction. Thus, the taper angle α₁ in the first stage is made small and narrow (gentle relative to the central axis C) to reduce disturbances at the crystal growth interface, the taper angle α₂ in the second stage is somewhat increased as compared with α₁ to cause the shoulder portion 11 to further spread in the diametric direction, and the taper angle α₃ in the third stage is further increased as compared with α₂ to allow the shoulder portion to much further widen in the diametric direction.

Since the way of increasing the taper angle is configured to be gradual in that manner, no great disturbances will occur at the crystal growth interface in each stage of taper angle changes and dislocations can be effectively inhibited from occurring. As mentioned later herein, it is very difficult, from the operational viewpoint, to proceed to growing of the main body portion immediately after forming a plain shoulder portion of a single taper of α₃; as a matter of fact, the transfer is performed gradually with a certain margin of time.

In the case where the number of stages resulting from varying the taper angle is three (α₁, α₂ and α₃), the angle α₁ is desirably selected within the range of 1° to 120°, α₂ within the range of 10° to 160°, and α₃ within the range of 20° to 175°. When any of the taper angles α₁, α₂ and α₃ is in excess of the upper limit to the corresponding range mentioned above, dislocations are readily occurred and, when any of the taper angles is below the lower limit of the corresponding range mentioned above, the growth (spreading) of the shoulder portion in the diametric direction gets slow and premature, and hence the main body portion becomes short and the productivity is reduced accordingly.

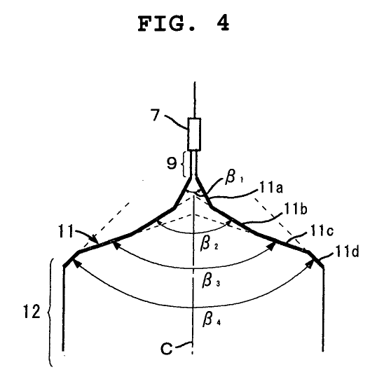

FIG. 4 is a figure for illustrating the shoulder formation method of the present invention, and is a schematic representation of yet another silicon single crystal at a certain time point in the course of pulling up the same as shown in vertical cross section showing the central axis of the silicon single crystal. This is the case where the taper angle is caused to vary in four stages, corresponding to the second embodiment as mentioned above. The taper angle is varied in four stages, namely β₁, β₂, β₃ and β₄, in that order on the occasion of forming the shoulder portion 11 (indicated by bold solid lines in the figure) extending from the neck portion 9 to the main body portion 12, as shown in FIG. 4.

In this case, the respective taper angles should satisfy the relations β₁<β₂<β₃ and β₃>β₄. The condition β₁<β₂<β₃ should be satisfied so that the occurrence of dislocations may be effectively inhibited and the productivity may be increased by causing the shoulder portion to sharply widen in the diametric direction, like in the case of causing the taper angle to vary in three stages.

Like in the case of causing the taper angle to vary in three stages (α₁, α₂ and α₃), it is desirable that the angle β₁ be selected within the range of 1° to 120°, β₂ within the range of 10° to 160° and β₃ within the range of 20° to 175°. When any of the taper angles β₁, β₂ and β₃ is in excess of the upper limit of each range mentioned above, dislocations are readily occurred and, when any of the taper angles is below the lower limit of each range mentioned above, the main body portion becomes short, and hence the productivity is reduced accordingly.

On the other hand, the condition β₃>β₄ should be satisfied so that it may become possible to smoothly proceed to the main body portion formation from the shoulder formation step. If the main body portion formation is to be started directly from the condition in which the taper angle is β₃, it becomes necessary to rapidly raise the melt temperature and rapidly increase the pulling speed to terminate the diametric growth of the shoulder portion; from the operational viewpoint, it is very difficult to produce these effects and, in some cases, troubles may be encountered, for example the shoulder portion may bulge out in excess of the predetermined main body portion diameter. Such a trouble may also serve as a factor causing disturbances at the crystal growth interface. Therefore, the fourth taper angle change is made while selecting the taper angle β₄ so as to satisfy the condition β₃>β₄, thereby avoiding sudden changes in proceeding to the main body portion growing from the shoulder formation step.

The taper angle β₄ is desirably selected within the range of 15° to 170°. When β₄ is in excess of the upper limit to the above range, the shoulder portion may possibly bulge out of the main body portion and, when it is below the lower limit of the above range, it becomes impossible to avoid sudden changes in melt temperature and pulling speed (both changes for increasing).

### EXAMPLES

Specific examples of the procedure (in particular, single crystal pulling speed and melt temperature controlling) in practicing the shoulder formation method of the present invention are now conceptually illustrated for the case where the taper angle is varied in four stages, as shown in FIG. 4.

Table 1 summarizes pulling speeds (high to low) and the extents of adjustment in melt temperature (extent of increase or decrease) in the respective stages resulting from varying the taper angle in the shoulder formation step.

In the table, the step 1, step 2, step 3 and step 4 respectively correspond to the shoulder portion regions (11a, 11b, 11c and 11d) formed upon varying of the taper angle from the first stage to the fourth stage (cf. FIG. 4). The high-to-low pulling speeds and the extents of adjustment in melt temperature are relatively represented for respective stages in the shoulder formation step.

TABLE 1

| | Step 1 | Step 2 | Step 3 | Step 4 |
|---|---|---|---|---|
| Pulling | High | Medium | Low | High |
| speed | | | | |
| Melt | Small | Medium | Large | Small |
| temperature | decrement | decrement | decrement | decrement or |
| | | | | small |
| | | | | increment |

First, in the step 1, the pulling speed is set at a rather high level and the melt temperature is lowered to a small extent. While the lowering of the melt temperature promotes the crystallization, causing the crystal to grow in a diametric direction, the shoulder portion acquires a gentle tapered shape relative to the central axis C, as shown in FIG. 4, owing to yet high level of pulling speed.

In the step 2, the pulling speed is lowered to a small extent and the extent of lowering the melt temperature is much more than in the step 1, so that the crystal growth in a diametric direction is promoted as compared with the step 1 and the gradient of the shoulder portion relative to the central axis C becomes increased/steeper.

In the step 3, the pulling speed is further lowered and the melt temperature is lowered to a maximum extent, so that the gradient of the shoulder portion becomes much steeper, coming close to a horizontal direction, and the shoulder portion formation proceeds in that condition toward the vicinity of the diameter of the main body portion.

In the step 4, the pulling speed is set at a rather high level and the melt temperature is lowered to a small extent or conversely raised to a small extent. By this, the diametric growth of the crystal is progressively retarded and the shoulder portion gradient becomes progressively decreased before reaching the starting position of the main body portion diameter; the shoulder formation step is thus completed.

By following the procedure basically as mentioned above in the shoulder formation step, it becomes possible to inhibit the occurrence of dislocations and thereby improve the yield so as to contribute to an improvement in productivity. Further, by carrying out the shoulder portion-spreading procedure by increasing the angle in a stepwise manner, it becomes possible to increase the main body portion length relative to the whole length of the single crystal pulled up, without causing reduction in productivity for silicon single crystals.

The shoulder formation method of the present invention (including the above-mentioned first and second embodiments) can be suitably utilized in growing large-diameter silicon single crystals having a diameter of 450 mm.

Conventionally, for ordinary single crystals, the shoulder portion formation is carried out based on the experience accumulated in actual operations, taking the main body portion productivity into consideration so that dislocations may be inhibited from occurring, but it has been very difficult to grow large-diameter silicon single crystals having a diameter of 450 mm, for instance, while securing high levels of productivity and reliably inhibiting the occurrence of dislocations in the shoulder formation step, in view of premature experiences and expertise of actual operations for growing such single crystals. However, when the shoulder formation method of the present invention including the above-mentioned embodiments is applied, it is possible to suppress disturbances to the minimum level in each stage of taper angle changes and inhibit the occurrence of dislocations by increasing the taper angle in a stepwise manner.

Further, it can be prospected that more desirable operational control limits, including the more desirable number of stages resulting from varying the taper angle, the desirable range of taper angle in each stage and the operational techniques therefor, may be established by accumulating the commercial operation results obtainable by applying the shoulder formation method of the present invention to the growth of large-diameter silicon single crystals; such obtainable results will further increase the efficacy of the shoulder formation method of the invention.

The above-mentioned shoulder formation method of the present invention (including the embodiments mentioned above) is a method comprising varying the taper angle of the shoulder portion in least two stages in growing silicon single crystals by the CZ method; when this method of growing silicon single crystals is carried out under application of a transverse magnetic field with an intensity of not less than 0.1 T, the effect of application of the transverse magnetic field can be obtained in addition to the effects of the present invention.

The application of such a transverse magnetic field on the occasion of growing silicon single crystals inhibits the convection of the melt in the crucible and markedly reduces temperature changes in the vicinity of the crystal growth interface, so that the concentration distribution of such a dopant as phosphorus to be introduced into the crystal and of other impurities is rendered uniform. Further, the introduction of point defects into the crystal is inhibited, so that crystals suited for wafer manufacture can be obtained in high yield; furthermore, the rate of crystal growth can be increased.

In this manner, by applying the shoulder formation method of the present invention under such a condition that a transverse magnetic field is applied, it becomes possible to grow silicon single crystals free of point defects with high production efficiency in addition to the effects of the present invention, namely the effects of inhibiting dislocations from occurring in the shoulder formation step and thereby improving the yield and increasing the productivity.

The intensity of the transverse magnetic field should be not less than 0.1 T since, at levels below 0.1 T, the convection of the melt is retarded only to an insufficient extent, and hence the effect of transverse magnetic field application is not produced to a full extent. The upper limit thereof is not particularly specified herein but is desirably set at 0.7 T or less since when an excessively intense transverse magnetic field is employed, the equipment for magnetic field application becomes large in size and the electric power consumption increases.

As described hereinabove, the shoulder formation method of the present invention to be applied in growing silicon single crystals comprises forming the shoulder portion while causing the taper angle thereof to vary in at least two stages in growing silicon single crystals by the CZ method, and can prevent dislocations from occurring in the shoulder formation step and thereby improve the yield and increase the productivity. An increased number of stages resulting from varying the taper angle is desirable since possible disturbances at respective crystal growth interfaces, which cause dislocations to occur, can be reduced.

The shoulder formation method of the present invention can be suitably utilized in growing large-diameter silicon single crystals having a diameter of 450 mm. Further, by applying the shoulder formation method of the present invention under the condition such that a transverse magnetic field with a predetermined intensity is applied, it becomes possible to grow defect-free silicon single crystals suited for the manufacture of wafers with high production efficiency while inhibiting dislocations from occurring in the above-mentioned shoulder formation step.

Therefore, the shoulder formation method of the present invention in growing silicon single crystals can be effectively utilized in the production of a silicon single crystal, in particular the one having a large diameter, for use in the field of manufacturing semiconductor devices.

1. A method of shoulder formation in growing silicon single crystals by the Czochralski method, comprising causing a taper angle in transition from a neck portion to a main body portion to vary in at least two stages.

2. The method of shoulder formation in growing silicon single crystals according to claim 1, wherein the growth of each silicon single crystal is carried out under application of a transverse magnetic field with an intensity of not less than 0.1 T.

3. The method of shoulder formation in growing silicon single crystals according to claim 1, wherein the taper angle is caused to vary in three stages with α₁, α₂ and α₃ in turn, and the condition α₁<α₂<α₃ is satisfied.

4. The method of shoulder formation in growing silicon single crystals according to claim 3, wherein the taper angle is caused to vary in three stages with the taper angle a, being selected within the range of 1° to 120°, α₂ within the range of 10° to 160° and α₃ within the range of 20° to 175°, respectively.

5. The method of shoulder formation in growing silicon single crystals according to claim 3, wherein the growth of each silicon single crystal is carried out under application of a transverse magnetic field with an intensity of not less than 0.1 T.

6. The method of shoulder formation in growing silicon single crystals according to claim 1, wherein the taper angle is caused to vary in four stages with β₁, β₂, β₃ and β₄ in turn, and the conditions β₁<β₂<β₃ and β₃>β₄ are satisfied.

7. The method of shoulder formation in growing silicon single crystals according to claim 6, wherein the taper angle is caused to vary in four stages with the taper angle β₁ being selected within the range of 1° to 120°, β₂ within the range of 10° to 160°, β₃ within the range of 20° to 175° and β₄ within the range of 15° to 170°, respectively.

8. The method of shoulder formation in growing silicon single crystals according to claim 6, wherein the growth of each silicon single crystal is carried out under application of a transverse magnetic field with an intensity of not less than 0.1 T.

9. The method of shoulder formation in growing silicon single crystals according to wherein the grown silicon single crystal is to have a diameter of 450 mm.

10. The method of shoulder formation in growing silicon single crystals according to claim 2, wherein the grown silicon single crystal is to have a diameter of 450 mm.

11. The method of shoulder formation in growing silicon single crystals according to claim 3, wherein the grown silicon single crystal is to have a diameter of 450 mm.

12. The method of shoulder formation in growing silicon single crystals according to claim 4, wherein the grown silicon single crystal is to have a diameter of 450 mm.

13. The method of shoulder formation in growing silicon single crystals according to claim 5, wherein the grown silicon single crystal is to have a diameter of 450 mm.

14. The method of shoulder formation in growing silicon single crystals according to claim 6, wherein the grown silicon single crystal is to have a diameter of 450 mm.

15. The method of shoulder formation in growing silicon single crystals according to claim 7, wherein the grown silicon single crystal is to have a diameter of 450 mm.

16. The method of shoulder formation in growing silicon single crystals according to claim 8, wherein the grown silicon single crystal is to have a diameter of 450 mm.
